(19) United States
(12) Patent Application Publication
(10) Pub. No.: US 2026/0221903 A1
(43) Pub. Date: Jul. 30, 2026

(54) ELECTROSTATIC CHUCK DEVICE

(71) Applicant: SUMITOMO OSAKA CEMENT CO., LTD., Tokyo (JP)

(72) Inventors: Atsushi FUMIKURA, Tokyo (JP); Yukio MIURA, Tokyo (JP)

(73) Assignee: SUMITOMO OSAKA CEMENT CO., LTD., Tokyo (JP)

(21) Appl. No.: 19/142,624

(22) PCT Filed: Mar. 19, 2024
(86) PCT No.: PCT/JP2024/010739

§ 371 Date: Jun. 23, 2025

(30) Foreign Application Priority Data
Mar. 22, 2023 (JP) 2023-044934

(51) Int. Cl. H02N 13/00

(52) U.S. Cl. CPC H02N 13/00

(57) ABSTRACT

An electrostatic chuck device includes: an electrostatic chuck member including a ceramic material; a base including silicon carbide as a material; and a joining layer formed of a metal material and configured to join the electrostatic chuck member and the base to each other, in which when a total volume of the electrostatic chuck member is represented by 100% by volume, the electrostatic chuck member includes 50% by volume or more of aluminum oxide, and when a total volume of the base is represented by 100% by volume, the base includes 75% by volume or more and 100% by volume or less of the silicon carbide.

### TECHNICAL FIELD

The present invention relates to an electrostatic chuck device.

### BACKGROUND ART

In the related art, in a semiconductor manufacturing process for manufacturing a semiconductor such as an IC, an LSI, or a VLSI, an electrostatic chuck device that electrostatically adsorbs a plate-shaped sample in a case of carrying out a plasma treatment on the plate-shaped sample such as a silicon wafer is used. With regard to the plate-shaped sample held by the electrostatic chuck device, the temperature distribution during the plasma treatment is uniformly controlled such that unevenness does not occur in the treatment state of the plate-shaped sample in the plasma treatment.

In recent years, with the diversification of semiconductor processes, the temperature of a plate-shaped sample during the treatment has been controlled within a wider temperature range than in the related art. Therefore, the electrostatic chuck device is exposed to a heat cycle in a wider temperature width than the related art.

Accordingly, an electrostatic chuck device having an electrostatic chuck member formed of a ceramic and a base formed of a metal matrix composite (MMC) which is a composite material of a metal and a ceramic has been proposed as the electrostatic chuck device (for example, see Patent Literature No. 1).

In the electrostatic chuck device described in Patent Literature 1, the electrostatic chuck member and the base are joined using a metal brazing material. In the electrostatic chuck device described in Patent Literature 1, by adjusting the amount of the metal in the MMC that is the material of the base, a difference in thermal expansion from a ceramic plate is reduced to be a reference value or less, and thermal stress during brazing is relieved.

### CITATION LIST

### Patent Literature

Patent Literature No. 1: Japanese Laid-open Patent Publication No. H11-163109

### SUMMARY OF INVENTION

### Technical Problem

However, from the viewpoint of obtaining an electrostatic chuck device having high heat resistance, there is still room for improvement.

The present invention has been made under these circumstances, and an object thereof is to provide a novel electrostatic chuck device having high heat resistance.

### Solution to Problem

As a result of various investigations by the present inventors, it was found that, when a base formed of MMC is adjusted and manufactured, there may be a problem with simple adjustment performed from the viewpoint of “reducing a difference in thermal expansion coefficient from a ceramic (electrostatic chuck member)”. The present inventors conducted thorough investigation based on the above-described findings, thereby completing the present invention.

The present invention provides an electrostatic chuck device including: an electrostatic chuck member including a ceramic material; a base including silicon carbide as a material; and a joining layer formed of a metal material and configured to join the electrostatic chuck member and the base to each other, in which when a total volume of the electrostatic chuck member is represented by 100% by volume, the electrostatic chuck member includes 50% by volume or more of aluminum oxide.

Specifically, the present invention provides the following aspects.

A first aspect of the present invention provides the following electrostatic chuck device.
[1] An electrostatic chuck device includes: an electrostatic chuck member including a ceramic material; a base including silicon carbide as a material; and a joining layer formed of a metal material and configured to join the electrostatic chuck member and the base to each other, in which when a total volume of the electrostatic chuck member is represented by 100% by volume, the electrostatic chuck member includes 50% by volume or more of aluminum oxide, and when a total volume of the base is represented by 100% by volume, the base includes 75% by volume or more and less than 100% by volume of the silicon carbide.

It is preferable that the first aspect of the present invention includes any one or a combination of two or more among the following characteristics [2] and [6] to [9].
[2] In the electrostatic chuck device according to [1], the joining layer includes a stress relief layer, a first joining layer configured to join the stress relief layer and the electrostatic chuck member to each other, and a second joining layer configured to join the stress relief layer and the base to each other.

A second aspect of the present invention provides the following electrostatic chuck device.
[3] An electrostatic chuck device includes: an electrostatic chuck member including a ceramic material; a base formed of silicon carbide; and a joining layer formed of a metal material and configured to join the electrostatic chuck member and the base to each other, in which the joining layer includes a stress relief layer, a first joining layer configured to join the stress relief layer and the electrostatic chuck member to each other, and a second joining layer configured to join the stress relief layer and the base to each other, and when a total volume of the electrostatic chuck member is represented by 100% by volume, the electrostatic chuck member includes 50% by volume or more of aluminum oxide.

It is preferable that the second aspect of the present invention includes any one or a combination of two or more among the following characteristics [6] to [9].

A third aspect of the present invention provides the following electrostatic chuck device.
[4] An electrostatic chuck device includes: an electrostatic chuck member including a ceramic material; a base formed of a metal matrix composite; and a joining layer formed of a metal material and configured to join the electrostatic chuck member and the base to each other, in which the joining layer includes a stress relief layer, a first joining layer configured to join the stress relief layer and the electrostatic chuck member to each other, and a second joining layer configured to join the stress relief layer and the base to each other, when a total volume of the electrostatic chuck member is represented by 100% by volume, the electrostatic chuck member includes 50% by volume or more of aluminum oxide, and when a total volume of the metal matrix composite is represented by 100% by volume, the metal matrix composite includes 75% by volume or more of silicon carbide and 0% by volume or more and 25% by volume or less of a metal having a melting point of 500° C. or higher and 700° C. or lower.

It is preferable that the third aspect of the present invention includes any one or a combination of two or more among the following characteristics [5] to [9].
[5] In the electrostatic chuck device according to [4], a surface of the base is covered with a metal film.
[6] In the electrostatic chuck device according to any one of [2] to [5], the stress relief layer is a metal layer or metal foil that is formed of at least one metal selected from the group consisting of Cu, Al, Ti, Nb, and W as a material, materials of the first joining layer and the second joining layer have a lower melting point than the material for forming the stress relief layer, and when a total volume of the first joining layer is represented by 100% by volume, the material of the first joining layer is an alloy that includes 50% by volume or more of Al or Ag and 0.02% by volume or more and 40% by volume or less of at least one metal selected from the group consisting of Ti, Zr, and Hf.
[7] In the electrostatic chuck device according to [6], the first joining layer and the second joining layer are formed of the same material.
[8] The electrostatic chuck device according to any one of [1] to [7], further includes: a supporting plate provided on a side of the base opposite to the electrostatic chuck member, in which the supporting plate is formed of a material having a higher Young's modulus than a material of the base.
[9] In the electrostatic chuck device according to any one of [1] to [7], the electrostatic chuck member includes a dielectric substrate and an adsorption electrode positioned in the dielectric substrate, in which the dielectric substrate is formed of the ceramic material.

### Advantageous Effects of Invention

According to the present invention, it is possible to provide a novel electrostatic chuck device having high heat resistance.

### BRIEF DESCRIPTION OF DRAWINGS

FIG. 1 A schematic cross-sectional view illustrating an example of an electrostatic chuck device 1A according to a first embodiment.

FIG. 2 A diagram illustrating an example of an electrostatic chuck device 1B according to a second embodiment.

FIG. 3 A graph in which, regarding each of specimens, the horizontal axis represents the number of cycles (times) and the vertical axis represents the amount of dimensional change (mm).

FIG. 4 An enlarged cross-sectional view illustrating a base according to Comparative Example 1 after a heat cycle test.

### DESCRIPTION OF EMBODIMENTS

Hereinafter, examples of a preferable embodiment of the present invention will be described with reference to the drawings. In addition, the following description is made for better understanding of the scope of the invention, and does not limit the present invention unless otherwise specified. Within a range not departing from the present invention, changes, omissions, or additions can be made for a number, a position, a size, an amount, a numerical value, a ratio, an order, a shape, a kind, a member, or the like. In addition, unless there is a particular problem, preferable conditions may be interchangeably used for a first embodiment and a second embodiment.

### First Embodiment

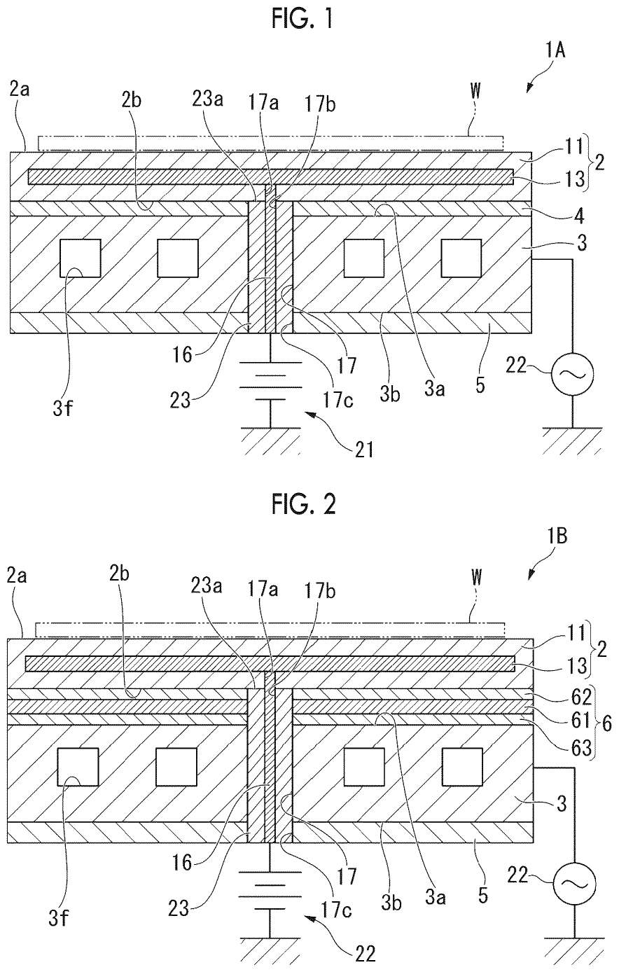

Hereinafter, a preferable example of an electrostatic chuck device according to a first embodiment of the present invention will be described with reference to FIG. 1. In all of the following drawings, dimensions, ratios, and the like of the components may be appropriately different from the actual ones in order to easily understand the drawings.

FIG. 1 is a schematic cross-sectional view illustrating an example of an electrostatic chuck device 1A according to the first embodiment. The electrostatic chuck device 1A includes an electrostatic chuck member 2, a base 3, a joining layer 4, a supporting plate 5, an insulator (insertion component) 23, and a feeding terminal 16. The electrostatic chuck member 2 and the base 3 are stacked through the joining layer 4.

In the present specification, a direction in which the electrostatic chuck member 2 and the base 3 are stacked will be referred to as a stacking direction. Further, a side of the base 3 where the electrostatic chuck member 2 is disposed will be referred to as one side in the stacking direction, and the opposite side thereof will be referred to as another side in the stacking direction. In addition, in the following description, assuming that an up-down direction is the stacking direction, each of units in the electrostatic chuck device 1A will be described. Note that the up-down direction described herein is merely a direction used for simplifying the description, and does not limit a position when the electrostatic chuck device 1A is used. The upper side corresponds to the one side in the stacking direction, and the lower side corresponds to the other side in the stacking direction.

### Electrostatic Chuck Member

The electrostatic chuck member 2 includes a dielectric substrate 11 and an adsorption electrode 13 positioned inside the dielectric substrate 11. A placement surface 2a for adsorbing a wafer W is provided on an upper surface of the electrostatic chuck member 2. A focus ring surrounding the wafer W may be disposed outside the placement surface 2a of the electrostatic chuck member 2. The electrostatic chuck member may have other characteristics as necessary. For example, an insulating layer may be provided around the adsorption electrode 13 as necessary. Two dielectric substrates 11 having the same composition or different compositions may be disposed above and below the adsorption electrode 13 or the insulating layer, respectively. The electrostatic chuck member 2 may be formed, for example, using a ceramic consisting of only an insulating material or using a ceramic consisting of a composite or a composite sintered body of an insulating material and a conductive material. In the description, a ceramic will also be referred to as a ceramic material.

It is preferable that the dielectric substrate 11 is formed of a composite sintered body having a sufficient mechanical strength and durability against corrosive gas and plasma thereof. As a dielectric material forming the dielectric substrate 11, a ceramic having a mechanical strength and durability against corrosive gas and plasma thereof is suitably used.

The ceramic (ceramic material) forming the dielectric substrate 11 can be selected as necessary, and preferably includes aluminum oxide (Al₂O₃) as a main component. “Main component” refers to a component that occupies 50% by volume or more with respect to the total volume. The content of aluminum oxide in the ceramic is preferably 60% by volume or more, 70% by volume or more, 80% by volume or more, 90% by volume or more, 95% by volume or more, or 100% by volume. As an example of the ceramic material, an aluminum oxide (Al₂O₃) sintered body, an aluminum oxide (Al₂O₃)-silicon carbide (SiC) composite sintered body, or the like is suitably used. In particular, from the viewpoints of dielectric characteristics, high corrosion resistance, plasma resistance, and heat resistance at a high temperature, the material forming the dielectric substrate 11 is preferably an Al₂O₃—SiC composite sintered body including aluminum oxide and silicon carbide.

The dielectric substrate 11 has a circular shape or a substantially circular plate shape in a plan view. The dielectric substrate 11 includes: the placement surface 2a on which the wafer W is placed; and a back surface 2b that faces the side opposite to the placement surface 2a. In the placement surface 2a, for example, a plurality of protrusion portions (not illustrated) may be formed at predetermined intervals. In this case, the placement surface 2a supports the wafer W at tip portions of the plurality of protrusion portions.

The adsorption electrode 13 is disposed inside the dielectric substrate 11. The adsorption electrode 13 is not exposed to the outside. The adsorption electrode 13 extends in a plate shape along the placement surface 2a of the dielectric substrate 11. By applying a voltage, the adsorption electrode 13 generates an electrostatic adsorption force to hold the wafer W in the placement surface 2a of the dielectric substrate 11. The feeding terminal 16 for applying a direct current voltage to the adsorption electrode 13 is connected to the adsorption electrode 13. The shape or number of the adsorption electrode 13 may be freely selected.

It is preferable that the adsorption electrode 13 is formed of a composite or a composite sintered body of an insulating material and a conductive material. It is also preferable that the insulating material is a ceramic. The insulating material in the adsorption electrode 13 is not particularly limited, and is preferably, for example, at least one selected from the group consisting of aluminum oxide (Al₂O₃), aluminum nitride (AlN), silicon nitride (Si₃N₄), yttrium (III) oxide (Y₂O₃), yttrium-aluminum-garnet (YAG), and SmAlO₃. The conductive material in the adsorption electrode 13 is preferably at least one selected from the group consisting of molybdenum carbide (Mo₂C), molybdenum (Mo), tungsten carbide (WC), tungsten (W), tantalum carbide (TaC), tantalum (Ta), silicon carbide (SiC), carbon black, carbon nanotubes, and carbon nanofibers. In the composite or the composite sintered body, a content ratio (compound ratio) between the conductive material and the insulating material is not particularly limited and may be freely selected depending on the use. For example, the content of the insulating material in the adsorption electrode 13 with respect to the total volume may be less than 95% by volume, less than 90% by volume, less than 70% by volume, less than 50% by volume, 30% by volume or less, 20% by volume or less, or 10% by volume or less, but is not limited to only these examples.

The thickness of the electrostatic chuck member 2 is freely selected and is preferably 0.5 mm or more and 5 mm or less. For example, the thickness may be 1.0 to 4 mm or 2.0 to 3 mm. When the thickness of the electrostatic chuck member 2 is 0.5 mm or more, the withstand voltage of the electrostatic chuck member 2 increases. In addition, when the thickness of the electrostatic chuck member 2 is 5 mm or less, the heat capacity of the electrostatic chuck member 2 is small. Therefore, the temperature of the plate-shaped sample, which is an object to be treated, is likely to be uniformly maintained during the plasma treatment.

When the total volume of the electrostatic chuck member is represented by 100% by volume, the electrostatic chuck member 2 may include 50% by volume or more, 60% by volume or more, 70% by volume or more, 80% by volume or more, or 90% by volume or more of aluminum oxide.

### Base

The base 3 supports the electrostatic chuck member 2 from the lower side. On the base 3, a support surface 3a facing upward and a lower surface 3b facing downward are provided. The support surface 3a faces the back surface 2b of the dielectric substrate 11 through the joining layer 4 in the up-down direction. The base 3 supports the electrostatic chuck member 2 on the support surface 3a.

In the base 3, a flow channel 3f for circulating a coolant is preferably provided. As the coolant flowing through the flow channel 3f, water, He gas, N₂ gas, or the like is adopted as necessary. The flow channel 3f extends along the support surface 3a. The coolant in the flow channel 3f cools the entire base 3, and cools the electrostatic chuck member 2 through the support surface 3a.

The base 3 is a disk-shaped or substantially disk-shaped member in a plan view, and is preferably formed of a material having a thermal conductivity of 140 W/m·K or higher. In the present specification, “plan view” refers to a field of view seen from a thickness direction of the electrostatic chuck member 2. The thermal conductivity may be 160 W/m·K or higher, 180 W/m·K or higher, 200 W/m·K or higher, 300 W/m·K or higher, 500 W/m·K or higher, 600 W/m·K or higher, or the like.

The material of the base 3 can be freely selected, and the base 3 preferably includes SiC as the material. Specifically, when the total volume of the base 3 is represented by 100% by volume, the material of the base 3 includes preferably 75% by volume or more of SiC, more preferably 75% by volume or more and less than 100% by volume of SiC, and still more preferably 75% by volume or more and 99% by volume or less. The above-described amount may be 80 to 98% by volume. 82 to 96% by volume, 85 to 90% by volume, or the like. It is preferable that the base 3 includes one or more of aluminum (Al), silicon (Si), and magnesium (Mg) in addition to SiC. The amount of these elements may be, for example, 0.1 to 25% by volume, 0.5 to 23% by volume, 1 to 22% by volume, 3 to 21% by volume, 5 to 20% by volume, or 10 to 15% by volume. By including these elements in addition to SiC, the thermal conductivity of the base 3 is improved, and heat dissipation through the base 3 is facilitated. In a material including 75% by volume or more of SiC as the material of the base 3, by adjusting the kind, amount, or the like of a counterpart material in the material, the thermal expansion coefficient can be controlled in a range of 2.8×10⁻⁶/K to 6.8×10⁻⁶/K. The thermal expansion coefficient may be in a range of 3.2 to 6.5×10⁻⁶/K, 3.6 to 6.0×10⁻⁶/K, 3.8 to 5.5×10⁻⁶/K, 4.0 to 5.0×10⁻⁶/K, or the like as necessary.

For example, when the total volume of the base 3 is represented by 100% by volume, it is preferable that the material of the base 3 includes 75% by volume or more and 85% by volume or less of SiC and 15% by volume or more and 25% by volume or less of Si or Mg. For example, the amount of SiC may be 76 to 84% by volume, 77 to 83% by volume, 78 to 82% by volume, or 80 to 81% by volume. The amount of Si or Mg may be 16 to 24% by volume, 17 to 23% by volume, 18 to 22% by volume, 20 to 21% by volume, or the like. In the base 3 having the above-described composition, the thermal expansion coefficient is very close to that of Al₂O₃—SiC forming the electrostatic chuck member, and distortion can be suppressed. It is also preferable that the base 3 is formed of SiC and only Al, Si, or Mg.

As an example of the material including Al, Si, Mg, or the like in addition to SiC, for example, a well-known metal material composite (hereinafter, referred to as MMC) can be preferably used. MMC may refer to a composite material of a metal and a ceramic, for example, a material where a ceramic reinforcement such as SiC is compounded with a metal matrix such as Al, Si, or Mg. MMC can be formed using any method, and can be preferably manufactured using, for example, a well-known method (a metal cementation method, a forging method, or the like) of adjusting or forming a porous ceramic substrate and subsequently introducing Al or Si into micropores of the ceramic substrate.

It is preferable that a surface of the base 3 is covered with a metal film as necessary. It is preferable that the metal film is provided on, for example, a front surface, a back surface, and a side surface of the base 3. The metal film can be selected as necessary. For example, an Al sprayed film can be adopted. A film thickness of the metal film can be freely selected and, for example, can be 100 μm or more and 300 μm or less. As a result, the base 3 can be used as an internal electrode for generating a plasma. From the viewpoint of suppressing discharge, it is also preferable that an insulating film, for example, an Al₂O₃ sprayed film is further provided on the side surface of the base 3 covered with the metal film. The base 3 is connected to an external high-frequency power supply 22 through a matching box (not illustrated).

A hole portion 17 is provided on the base 3. The hole portion 17 extends in the up-down direction. The hole portion 17 penetrates the base 3 in the up-down direction, and is formed on the support surface 3a and the lower surface 3b of the base 3. The hole portion 17 has, for example, a circular shape in a plan view. An insulator 23 described below is inserted into the hole portion 17. FIG. 1 illustrates that the hole portion 17 penetrates the base 3 in the up-down direction. As long as the hole portion 17 is formed in at least the support surface 3a such that the insulator 23 is inserted into the hole portion 17, the hole portion 17 does not need to penetrate the base 3.

### Joining Layer

The joining layer 4 is formed of a metal material, and joins the electrostatic chuck member 2 and the base 3 to each other. Examples of the metal material include a material consisting of only one or more metals and a material including one or more metals. For example, the metal material may be a layer consisting of one metal or may be an alloy layer including a plurality of metals. When the total volume of the joining layer 4 is represented by 100% by volume, it is preferable that the joining layer 4 is formed by using, as a forming material, an alloy including 50% by volume or more of Al or Ag as a main raw material and 0.02% by volume or more and 40% by volume or less of at least one metal selected from the group consisting of Ti, Zr, Hf, and Nb, for example, active metal selected from the group. The amount of Al or Ag may be 55 to 99.8% by volume, 60 to 98% by volume, 70 to 95% by volume, 80 to 90% by volume, or the like. The amount of the at least one metal may be 0.1 to 35% by volume, 1 to 30% by volume, 5 to 25% by volume, 10 to 20% by volume, or the like. The joining layer 4 includes at least one metal selected from the group consisting of Ti, Zr, Hf, and Nb. As a result, when the electrostatic chuck member 2 and the base 3 are joined, a molten alloy obtained by melting the material of the joining layer 4 is likely to wet and spread on the surface of the ceramic (electrostatic chuck member 2), which facilitates joining. In addition, since the joining layer 4 includes the above-described metal, the above-described metal and the ceramic (electrostatic chuck member 2) are likely to adhere to each other, the occurrence of a void at the interface can be suppressed, and strong joining can be achieved. The joining layer 4 may include one or more metals or elements other than the above-described metals or elements as necessary, or may include, for example, Cu or Sn.

When a brazing material in Ti as the active metal is used for forming the joining layer 4, when Ti is oxidized to form Ti oxide, junction failure is likely to occur. Therefore, when the brazing material in Ti is used for forming the joining layer 4, it is preferable that temperature conditions or pressure conditions during brazing are adjusted not to oxidize Ti in the brazing material.

Alternatively, the Ti film may be formed on at least one of the dielectric substrate 11 and the base 3 to bond these elements to a brazing material not including Ti for brazing. The Ti film may be a Ti sputtering film, or may be formed by applying a slurry including Ti fine powder and subsequently heating the applied slurry. In this case, the joining layer 4 is formed of the Ti film and the brazing material.

The thickness of the joining layer 4 can be freely selected and, for example, is preferably 0.005 mm or more and 0.5 mm or less. The thickness may be 0.01 to 0.3 mm, 0.05 to 0.1 mm, or the like.

When the electrostatic chuck device 1A is manufactured, a metal foil may also be used as the material of the joining layer 4, or a metal paste where a binder is added to metal powder may also be used. These materials are disposed between the electrostatic chuck member 2 and the base 3, and are heated to a temperature that is higher than or equal to a melting point of the metal material for forming the joining layer such that the molten metal material wets and spreads between the electrostatic chuck member 2 and the base 3. As a result, the joining layer 4 can be formed.

### Supporting Plate

The supporting plate 5 supports the base 3 from the lower surface 3b of the base 3. It is preferable that the supporting plate 5 is formed of a material having a higher Young's modulus than the material of the base 3. For example, as the material of the supporting plate 5, any one of a metal, MMC, and a ceramic can be adopted. In particular, as the supporting plate 5, a plate consisting of a ceramic, for example, a ceramic plate such as Al₂O₃ having a higher Young's modulus than the base 3 is preferable.

It is preferable that the ceramic used for the supporting plate 5 is the same as the ceramic (ceramic material) used for the electrostatic chuck member 2. For example, it is preferable that the ceramic forming the supporting plate 5 or the insulating material in the ceramic is the same as the ceramic forming the electrostatic chuck member 2 or the insulating material in the ceramic. Specific examples of the ceramic include aluminum oxide and aluminum nitride. By using the same material for the supporting plate 5 and the electrostatic chuck member 2, a difference in thermal expansion coefficient between the supporting plate 5 and the electrostatic chuck member 2 can be reduced, and warpage of the electrostatic chuck device 1A is suppressed.

### Insulator

The insulator 23 is inserted into the hole portion 17 to be assembled into the base 3. That is, the insulator 23 functions as an insertion component to be inserted into the hole portion 17. The insulator 23 has a cylindrical shape extending in the up-down direction (stacking direction). In the insulator 23, the feeding terminal 16 is disposed. An outer peripheral surface of the insulator 23 is joined to an inner side surface of the hole portion 17 using joining means such as adhesion. The insulator 23 insulates the base 3 and the feeding terminal 16 from each other. In FIG. 1 or 2, the insulator 23 is inserted into a hole of the joining layer 4, the hole portion of the base 3, and a hole of the supporting plate 5.

The insulator 23 can be formed of any material. For example, a ceramic can be used as the forming material. That is, the insulator 23 is formed of an insulating member. With this configuration, the insulator 23 can suppress a phenomenon in which a gas introduction hole causes abnormal discharge to occur. The insulator 23 has durability against a plasma. As the ceramic forming the insulator 23, for example, a ceramic including one or two or more selected from AlN, Al₂O₃, Si₃N₄, zirconium oxide (ZrO₂), sialon, boron nitride (BN), and SiC can be preferably adopted.

An end surface (hereinafter, an upper end surface 23a) of the insulator 23 on the upper side (one side in the stacking direction) is disposed to abut against a lower surface of the electrostatic chuck member 2 or to face the lower surface through an insulating adhesive positioned between the insulator 23 and the electrostatic chuck member. As long as the purpose of insulating the feeding terminal 16 can be achieved, conditions of the insulator 23 such as a position, a height, or a shape may be changed.

### Feeding Terminal

The feeding terminal 16 extends downward from the adsorption electrode 13. The feeding terminal 16 is connected to an external power supply 21. The power supply 21 applies a voltage to the adsorption electrode 13. The number, shape, and the like of the feeding terminals 16 can be freely selected and may be determined depending on, for example, the form of the adsorption electrode 13, that is, whether the adsorption electrode 13 is unipolar or bipolar.

The feeding terminal 16 is allowed to pass through a first hole 17a of the dielectric substrate 11, a second hole 17b of the joining layer 4, the hole portion 17 of the base 3, and a third hole 17c of the supporting plate 5. The first hole 17a is provided below the adsorption electrode 13 of the dielectric substrate 11. The insulator 23 is present between the feeding terminal 16 and the second hole 17b of the joining layer 4, the hole portion 17 of the base 3, and the third hole 17c of the supporting plate 5.

Each of the first hole 17a, the second hole 17b, the hole portion 17, and the third hole 17c has a circular shape when seen from the stacking direction. The first hole 17a, the second hole 17b, and the third hole 17c communicate with the hole portion 17 of the base 3.

In addition, an inner peripheral surface of the first hole 17a lies next to an inner peripheral surface of the insulator 23 when seen from the stacking direction. An inner diameter of the first hole 17a is substantially the same as an inner diameter of the insulator 23, and is slightly larger than an outer diameter of the feeding terminal 16. Inner diameters of the second hole 17b and the third hole 17c are slightly larger than an outer diameter of the insulator 23.

As a result of thorough investigation by the present inventors, it was found that, in the electrostatic chuck device according to the present invention, for example, the above-described electrostatic chuck device 1A shows an excellent result capable of enduring repeated use at a high temperature.

In the related art, for example, when a ceramic member such as the electrostatic chuck member 2 and a base are brazed, in order to suppress breakage caused by a difference in thermal expansion coefficient between members, materials are adjusted based on thinking of reducing the difference in thermal expansion coefficient between the members to be brazed to be as small as possible. For example, when Al₂O₃ is a main component of the electrostatic chuck member 2, the thermal expansion coefficient of the electrostatic chuck member 2 is 7 to 8(×10⁻⁶/K). From the above, according to the way of thinking in the related art, it has been known that the thermal expansion coefficient of the material of the base 3 to be joined to the electrostatic chuck member 2 is preferably 7 to 8(×10⁻⁶/K). In order to realize the small difference in thermal expansion coefficient as much as possible, in the related art, MMC having a thermal expansion coefficient of 7 to 8(×10⁻⁶/K) is adopted as the material of the base 3.

However, according to various investigations by the present inventors, it was found that, when the material of the base 3 is MMC, in the material forming the base 3, a void caused by a difference in thermal expansion is generated at an interface between a metal structure and a ceramic structure such that a change in the dimension or physical properties of the base 3 may occur. The present inventors verified that this problem occurs when a metal is introduced until the thermal expansion coefficient of the material of the base 3 reaches 7 to 8(×10⁻⁶/K).

Therefore, as a result of various investigations, it was found that, in the electrostatic chuck device according to the present embodiment, for example, in the above-described electrostatic chuck device 1A, the effect of suppressing the occurrence of the above-described problem can be obtained, for example, by increasing the proportion of the ceramic structure to adjust the content of SiC in the material of the base 3 to be 75% by volume or more such that there is a difference in thermal expansion coefficient from the electrostatic chuck member 2.

In the present embodiment, the difference between the thermal expansion coefficient of the electrostatic chuck member 2 and the thermal expansion coefficient of the material of the base 3 may be, for example, 0.1 to 7(×10⁻⁶/K), 0.5 to 5(×10⁻⁶/K), 1.0 to 5(×10⁻⁶/K), 2.0 to 4(×10⁻⁶/K), or 2.5 to 3.5(×10⁻⁶/K). However, the difference in thermal expansion coefficient is not limited to only these examples.

With the electrostatic chuck device having the above-described configuration, a novel electrostatic chuck device having high heat resistance can be provided.

### Second Embodiment

FIG. 2 is a diagram illustrating a preferable example of an electrostatic chuck device 1B according to a second embodiment of the present invention. The electrostatic chuck device 1B according to the present embodiment is partially common to the electrostatic chuck device 1A according to the first embodiment. Accordingly, in the present embodiment, components common to those of the first embodiment will be represented by the same reference numerals, and the detailed description will not be made.

The electrostatic chuck device 1B includes the electrostatic chuck member 2, the base 3, a joining layer 6, the supporting plate 5, the insulator (insertion component) 23, and the feeding terminal 16. The electrostatic chuck member 2 and the base 3 are stacked through the joining layer 6.

### Joining Layer

The joining layer 6 includes a stress relief layer 61, a first joining layer 62 configured to join the stress relief layer 61 and the electrostatic chuck member 2, and a second joining layer 63 configured to join the stress relief layer 61 and the base 3 to each other. The joining layer 6 has a higher thermal conductivity than the base 3.

The stress relief layer 61 is formed of a material that is easily plastically deformable, and relieves thermal stress generated by a difference in thermal expansion coefficient between the electrostatic chuck member 2 and the base 3. A material of the stress relief layer 61 is preferably a metal foil formed of at least one metal selected from the group consisting of Cu, Al, and Ti.

Alternatively, as the material of the stress relief layer 61, a material having a small difference in thermal expansion coefficient from the material such as Al₂O₃ forming the electrostatic chuck member 2 can also be used. Examples of a material that has a small difference in thermal expansion coefficient from the thermal expansion coefficient (7 to 7.7×10⁻⁶/K) of Al₂O₃ and is preferably used as the stress relief layer include Ti (8.4×10⁻⁶/K), Nb (7.1×10⁻⁶/K), and W (4.6×10⁻⁶/K). For example, the stress relief layer 61 may be a metal layer including or consisting of at least one selected from the group consisting of CU, Al, Ti, Nb, and W.

The thickness of the stress relief layer 61 can be freely selected, and is preferably 0.1 mm or more and 1 cm or less and more preferably 1 mm or more and 1 cm or less. For example, the thickness of the stress relief layer 61 may be 0.5 mm to 8 mm, 1 mm to 6 mm, or 3 to 5 mm. Since the thickness of the stress relief layer 61 is in the above-described range, thermal stress can be sufficiently relieved, and peeling between the electrostatic chuck member 2 and the base 3 can be suppressed.

It is preferable that materials of the first joining layer 62 and the second joining layer 63 have a lower melting point than the material for forming the stress relief layer. The first joining layer 62 and the second joining layer 63 may be the same material.

As the material of the first joining layer 62, the same material as that of the joining layer 4 according to the first embodiment can be adopted. For example, when the total volume of the first joining layer 62 is represented by 100% by volume, it is preferable that the material of the first joining layer 62 is an alloy including 50% by volume or more of Al or Ag and 0.02% by volume or more and 40% by volume or less of at least one metal selected from the group consisting of Ti, Zr, and Hf. For the second joining layer 63, the same material can also be adopted.

The thicknesses of the first joining layer 62 and the second joining layer 63 can be freely selected and, for example, may be 0.001 mm or more and 1.0 mm or less and are preferably 0.005 mm or more and 0.5 mm or less. The thicknesses may be 0.01 mm or more and 0.3 mm or less, 0.05 mm or more and 0.1 mm or less, or the like.

In a case where the joining layer 6 is included, when the total volume of the base 3 is represented by 100% by volume, it is preferable that the material of the base 3 includes 75% by volume or more and 100% by volume or less of SiC. For example, the amount of SiC may be 80 to 98% by volume, 82 to 96% by volume, or 85 to 90% by volume. In addition to SiC, the base 3 may include aluminum (Al), silicon (Si), or magnesium (Mg).

In addition, it is also preferable that the base 3 is formed of a metal matrix composite. When the base 3 is formed of the metal matrix composite and the total volume of the metal matrix composite is represented by 100% by volume, it is also preferable that the metal matrix composite includes 75% by volume or more of silicon carbide and 0% by volume or more and 25% by volume or less of a metal having a melting point of 500° C. or higher and 700° C. or lower. For example, the amount of silicon carbide may be 75 to 100% by volume, 78 to 99% by volume, 80 to 98% by volume, or 85 to 90% by volume. The amount of the metal may be 0.1 to 24% by volume, 0.5 to 22% by volume, 1 to 21% by volume, 2 to 20% by volume, 3 to 15% by volume, 5 to 10% by volume, or the like. The melting point of the metal may be 550° C. or higher and 680° C. or lower, 580° C. or higher and 630° C. or lower, or the like. Examples of the metal include Al (melting point: 660° C.) and Mg (melting point: 650° C.). When the melting point of the metal in the metal matrix composite is 500° C. or higher, the metal does not melt at an operating temperature of the electrostatic chuck. In addition, when the melting point of the metal is 700° C. or lower, the cost during manufacturing can be suppressed to be low.

When SiC (100% by volume) not including a metal structure is used as the material of the base 3, a void is not generated at an interface between the metal structure and the ceramic structure, and thus the occurrence of a void in the base 3 can be suppressed. On the other hand, however, when there is a difference in thermal expansion coefficient between the base 3 and the electrostatic chuck unit 2, stress is generated at an interface between the members due to this difference in thermal expansion, and interfacial peeling is likely to occur. Even in this case, since the joining layer 6 includes the stress relief layer 61, stress generated at the interface between the base 3 and the electrostatic chuck unit 2 can be relieved, and interfacial peeling can be suppressed.

Even in the electrostatic chuck device having the above-described configuration, a novel electrostatic chuck device having high heat resistance can be provided.

The preferred embodiment of the present invention has been described above with reference to the accompanying drawings. However, the present invention is not limited to such an example. The various shapes, combinations, and the like of the constituent members shown in the above examples are merely examples, and various modifications can be made based on design requirements and the like without departing from the gist of the present invention.

### EXAMPLES

Hereinafter, the present invention will be described with Examples. However, the present invention is not limited to the Examples.

### Evaluation 1

### Example 1 and 2 and Comparative Examples 1 and 2

An MMC that was adjusted and manufactured such that metal and SiC were compounded at a ratio shown in “Test Piece Composition” below was obtained as each of specimens (bases) according to Examples and Comparative Examples. The shapes or sizes of these specimens were the same.

### Test Piece Composition:

(Example 1) 18Si—SiC (SiC: 82% by volume and Si: 18% by volume)
(Example 2) 18Mg—SiC (SiC: 82% by volume and Mg: 18% by volume)
(Comparative Example 1) 30Al—SiC (SiC: 70% by volume and Al: 30% by volume)
(Comparative Example 2) 40Al—Si (Si: 60% by volume and Al: 40% by volume)
(Size: length and width: 50 mm, height: 12 mm, and shape: a rectangular parallelepiped)

### Heat Cycle Test

Using a 2-zone thermal shock tester, each of the obtained specimens was held in a test area (area 1) at 150° C. for 30 minutes, and subsequently was held in a test area (area 2) at −50° C. for 30 minutes. These operations were repeated multiple times. Specifically, an operation of increasing the temperature from −50° C. and then decreasing the temperature back to −50° C. was set as one cycle, and was repeated in 600 cycles at a maximum.

Regarding the specimen after the heat cycle test, the outer shape (diameter) of the base was measured, and a dimensional change before and after the test was evaluated. A base where a dimensional change after 500 or 600 cycles was 0.01 mm or less was determined as a non-defective product, and a base where a dimensional change after 500 or 600 cycles was more than 0.01 mm was determined as a defective product.

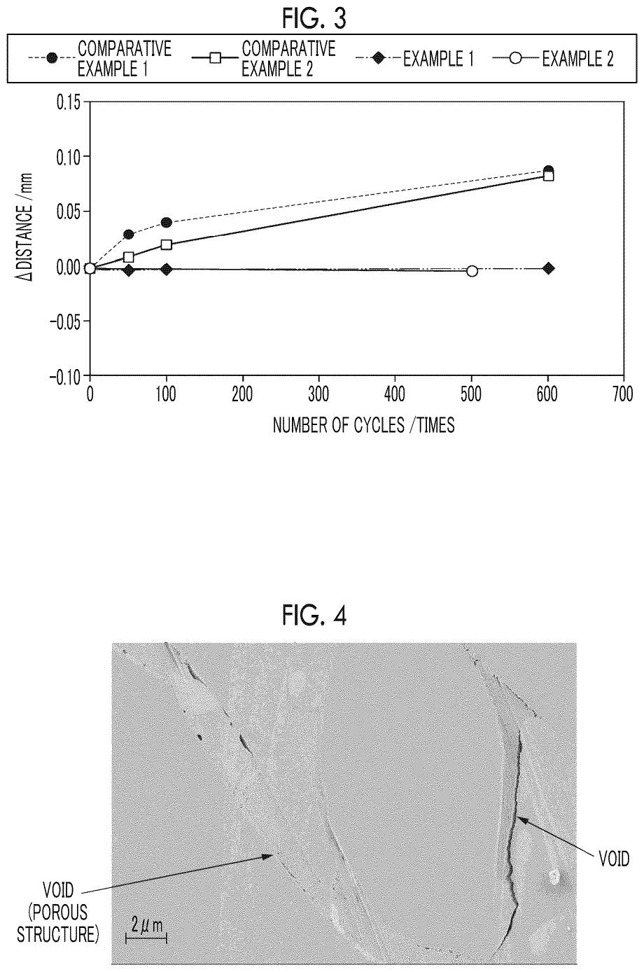

The evaluation results are illustrated in FIG. 3. FIG. 3 is a graph in which, regarding each of the specimens, the horizontal axis represents the number of cycles (times) and the vertical axis represents the amount of dimensional change (mm). The evaluation results show that, in the bases according to Examples 1 and 2, the dimensional change was small, and thus generation of stress at the interface between the electrostatic chuck member and the base was suppressed. The above shows that, when the base of the electrostatic chuck device includes 75% by volume or more of silicon carbide, the excellent effect can be obtained.

FIG. 4 is an enlarged cross-sectional view illustrating the base according to Comparative Example 1 after the heat cycle test. As illustrated in FIG. 4, it was able to be verified that the base according to Comparative Example was peeled off from an interface between the metal structure and crystal grains of the ceramic, and a void was formed. Imaging conditions of FIG. 4 are as follows.

### Imaging Conditions

Device: a field emission scanning electron microscope (FE-SEM) (Merlin, manufactured by Carl Zeiss)
EDX detector (Xflash 6, manufactured by Bruker)
Acceleration voltage: 1.0 kV (SEM observation)
Magnification: 5000-fold
Sample formation: a cross-section was prepared using a BIB method to obtain an evaluation sample.

### Evaluation 2

### Example 3, Comparative Example 3 (Reference Example)

Each of the specimens (stacked bodies) according to Example 3 and Comparative Example 3 was formed using the following method.

### Example 3

Using a method described below, a specimen (stacked body) was manufactured. The used material was as follows.
Ceramic plate: an Al₂O₃—SiC disk, diameter: 12 mm, thickness: 3 mm, manufactured by SUMITOMO OSAKA CEMENT Co., Ltd. (proportion of Al₂O₃: 95% by mass)
Base material: a SiC disk, diameter: 10 mm, thickness: 2 mm
Joining layer: a stacked body of metal brazing material (first joining layer)/copper plate (stress relief layer)/metal brazing material (second joining layer)

The above-described metal brazing material: TKC-661 (composition: Ag 66.0±1.0%, Cu 29.5±1.0%, Ti 1.5±0.5%, Sn remainder (about 3%)), manufactured by TANAKA PRECIOUS METAL TECHNOLOGIES Co., Ltd.,
diameter: 12 mm, thickness: 0.005 mm

The above-described copper plate: oxygen-free copper, diameter: 12 mm, thickness: 2 mm

### Comparative Example 3: Reference Example

The same material as that of Example 3 was used, except that only the above-described metal brazing material (first joining layer) was used as the joining layer. The thickness of the joining layer used in Comparative Example 3 was 0.005 mm.

### Method of Manufacturing Each of Specimens

A stacked body where a joining layer was interposed between a ceramic plate and a base material was formed and provided in a carbon jig, and a load (1.3 KPa) was applied thereto.

Next, the stacked body was heated under the following conditions. First, the stacked body was depressurized to 1×10⁻³ Pa or lower in a vacuum furnace, was heated by sequentially performing treatments of the following conditions (1) to (3), and was brazed. Next, the stacked body was allowed to cool to room temperature by performing a treatment of the following condition (4).

### Heating Conditions

1) The temperature was increased from room temperature to 300° C. and was held at 300° C. for 30 minutes.
2) The temperature was increased from 300° C. to 770° C. at 10° C./min and was held at 770° C. for 10 minutes.
3) The temperature was increased from 770° C. to 880° C. at 5° C./min and was held at 880° C. for 30 minutes.
4) The temperature was allowed to cool from 880° C. to room temperature.

Regarding the obtained specimen, an ultrasonic test was performed. As a result, a void was not able to be verified in the specimen according to Example 3, and a void was verified in the specimen according to Comparative Example 3. When there is expansion coefficient difference stress between the electrostatic chuck member and the base, the excellent effect by the joining layer including the relief layer was verified.

Evaluation conditions of the ultrasonic test are as follows.

### Evaluation Conditions

Device: an ultrasonic flaw detector (mode: IS600, manufactured by INSIGHT CO., LTD.)
Scan length: 20 mm
Scan pitch: 0.1 mm
Energy: LOW
Voltage: 330 V
Damping: 100Ω
Gain: 19 db
LPF: 300 MHz
HPF: 5 MHz

In addition, regarding each of the specimens, a cross-section was formed and observed with an optical microscope. As a result, no crack was able to be verified in the cross-section of the specimen according to Example 3, and a crack was verified in the cross-section of the specimen according to Comparative Example 3.

From the above results, it was verified that the present invention is useful.

### INDUSTRIAL APPLICABILITY

The present invention can provide a novel electrostatic chuck device having high heat resistance.

### REFERENCE SIGNS LIST

1A, 1B electrostatic chuck device
2 electrostatic chuck member
2a placement surface
2b back surface
3 base
3a support surface
3b lower surface
3f flow channel
4, 6 joining layer
5 supporting plate
11 dielectric substrate
13 adsorption electrode
16 feeding terminal
17 hole portion
17a first hole
17b second hole
17c third hole
21 power supply
22 external high-frequency power supply
23 insulator
23a upper end surface
61 stress relief layer
62 first joining layer
63 second joining layer
W wafer

1. An electrostatic chuck device comprising:
an electrostatic chuck member including a ceramic material;
a base including silicon carbide as a material; and
a joining layer formed of a metal material and configured to join the electrostatic chuck member and the base to each other,
wherein when a total volume of the electrostatic chuck member is represented by 100% by volume, the electrostatic chuck member includes 50% by volume or more of aluminum oxide, and
when a total volume of the base is represented by 100% by volume, the base includes 75% by volume or more and less than 100% by volume of the silicon carbide.

2. The electrostatic chuck device according to claim 1,
wherein the joining layer includes a stress relief layer,
a first joining layer configured to join the stress relief layer and the electrostatic chuck member to each other, and
a second joining layer configured to join the stress relief layer and the base to each other.

3. An electrostatic chuck device comprising:
an electrostatic chuck member including a ceramic material;
a base formed of silicon carbide; and
a joining layer formed of a metal material and configured to join the electrostatic chuck member and the base to each other,
wherein the joining layer includes
a stress relief layer,
a first joining layer configured to join the stress relief layer and the electrostatic chuck member to each other, and
a second joining layer configured to join the stress relief layer and the base to each other, and
when a total volume of the electrostatic chuck member is represented by 100% by volume, the electrostatic chuck member includes 50% by volume or more of aluminum oxide.

4. An electrostatic chuck device comprising:
an electrostatic chuck member including a ceramic material;
a base formed of a metal matrix composite; and
a joining layer formed of a metal material and configured to join the electrostatic chuck member and the base to each other,
wherein the joining layer includes
a stress relief layer,
a first joining layer configured to join the stress relief layer and the electrostatic chuck member to each other, and
a second joining layer configured to join the stress relief layer and the base to each other,
when a total volume of the electrostatic chuck member is represented by 100% by volume, the electrostatic chuck member includes 50% by volume or more of aluminum oxide, and
when a total volume of the metal matrix composite is represented by 100% by volume, the metal matrix composite includes 75% by volume or more of silicon carbide and 0% by volume or more and 25% by volume or less of a metal having a melting point of 500° C. or higher and 700° C. or lower.

5. The electrostatic chuck device according to claim 4,
wherein a surface of the base is covered with a metal film.

6. The electrostatic chuck device according to claim 5,
wherein the stress relief layer is a metal layer or metal foil that is formed of at least one metal selected from the group consisting of Cu, Al, Ti, Nb, and W as a material,
materials of the first joining layer and the second joining layer have a lower melting point than the material for forming the stress relief layer, and
when a total volume of the first joining layer is represented by 100% by volume, the material of the first joining layer is an alloy that includes 50% by volume or more of Al or Ag and 0.02% by volume or more and 40% by volume or less of at least one metal selected from the group consisting of Ti, Zr, and Hf.

7. The electrostatic chuck device according to claim 6,
wherein the first joining layer and the second joining layer are formed of the same material.

8. The electrostatic chuck device according to claim 1, further comprising:
a supporting plate provided on a side of the base opposite to the electrostatic chuck member,
wherein the supporting plate is formed of a material having a higher Young's modulus than a material of the base.

9. The electrostatic chuck device according to claim 2,
wherein the stress relief layer is a metal layer or metal foil that is formed of at least one metal selected from the group consisting of Cu, Al, Ti, Nb, and W as a material,
materials of the first joining layer and the second joining layer have a lower melting point than the material for forming the stress relief layer, and
when a total volume of the first joining layer is represented by 100% by volume, the material of the first joining layer is an alloy that includes 50% by volume or more of Al or Ag and 0.02% by volume or more and 40% by volume or less of at least one metal selected from the group consisting of Ti, Zr, and Hf.

10. The electrostatic chuck device according to claim 3,
wherein the stress relief layer is a metal layer or metal foil that is formed of at least one metal selected from the group consisting of Cu, Al, Ti, Nb, and W as a material,
materials of the first joining layer and the second joining layer have a lower melting point than the material for forming the stress relief layer, and
when a total volume of the first joining layer is represented by 100% by volume, the material of the first joining layer is an alloy that includes 50% by volume or more of Al or Ag and 0.02% by volume or more and 40% by volume or less of at least one metal selected from the group consisting of Ti, Zr, and Hf.

11. The electrostatic chuck device according to claim 4,
wherein the stress relief layer is a metal layer or metal foil that is formed of at least one metal selected from the group consisting of Cu, Al, Ti, Nb, and W as a material,
materials of the first joining layer and the second joining layer have a lower melting point than the material for forming the stress relief layer, and
when a total volume of the first joining layer is represented by 100% by volume, the material of the first joining layer is an alloy that includes 50% by volume or more of Al or Ag and 0.02% by volume or more and 40% by volume or less of at least one metal selected from the group consisting of Ti, Zr, and Hf.

12. The electrostatic chuck device according to claim 2, further comprising:
a supporting plate provided on a side of the base opposite to the electrostatic chuck member,
wherein the supporting plate is formed of a material having a higher Young's modulus than a material of the base.

13. The electrostatic chuck device according to claim 3, further comprising:
a supporting plate provided on a side of the base opposite to the electrostatic chuck member,
wherein the supporting plate is formed of a material having a higher Young's modulus than a material of the base.

14. The electrostatic chuck device according to claim 4, further comprising:
a supporting plate provided on a side of the base opposite to the electrostatic chuck member,
wherein the supporting plate is formed of a material having a higher Young's modulus than a material of the base.

15. The electrostatic chuck device according to claim 5, further comprising:
a supporting plate provided on a side of the base opposite to the electrostatic chuck member,
wherein the supporting plate is formed of a material having a higher Young's modulus than a material of the base.
